(19) United States
(12) Patent Application Publication
(10) Pub. No.: US 2016/0163762 A1
(43) Pub. Date: Jun. 9, 2016

(54) RADIATION IMAGE PICKUP UNIT AND RADIATION IMAGE PICKUP DISPLAY SYSTEM

(71) Applicant: SONY CORPORATION, TOKYO (JP)

(72) Inventor: YASUHIRO YAMADA, KANAGAWA (JP)

(73) Assignee: SONY CORPORATION, TOKYO (JP)

(21) Appl. No.: 14/905,041

(22) PCT Filed: Jul. 3, 2014
(86) PCT No.: PCT/JP2014/067752

§ 371 Date: Jan. 14, 2016

(30) Foreign Application Priority Data
Jul. 17, 2013 (JP) 2013-148271

(51) Int. Cl. H01L 27/146; H01L 31/119; H01L 29/423; H01L 31/117; H01L 29/786; H01L 29/51

(52) U.S. Cl. CPC H01L 27/14658; H01L 27/14616; H01L 29/78603; H01L 29/78663; H01L 29/78672; H01L 29/7869; H01L 29/513; H01L 29/518; H01L 29/42364; H01L 29/78648; H01L 27/1462; H01L 31/117; H01L 31/119

(57) ABSTRACT

There is provided a radiation image pickup unit including a plurality of pixels configured to generate signal charge based on radiation; and a field effect transistor for readout of the signal charge from the plurality of pixels, the transistor including a first silicon oxide film, a semiconductor layer including an active layer, and a second silicon oxide life stacked in order from substrate side, and a first gate electrode disposed to face the semiconductor layer with one of the first and the second silicon oxide films in between. The second silicon oxide film has a thickness equal to or larger than a thickness of the first silicon oxide film.

### TECHNICAL FIELD

The disclosure relates to a radiation image pickup unit obtaining an image based on, for example, radiation, and a radiation image pickup display system including such a radiation image pickup unit.

### BACKGROUND ART

There are proposed radiation image pickup units obtaining an image signal based on, for example, radiation such as X-rays (for example, see Patent Literatures 1 and 2).

### CITATION LIST

### Patent Literature

Patent Literature 1: Japanese Unexamined Patent Application Publication No. 2008-252074

Patent Literature 2: Japanese Unexamined Patent Application Publication No. 2004-265935

### SUMMARY OF INVENTION

In the foregoing radiation image pickup units, a thin film transistor (TFT) is used as a switching device for readout of signal charge from each pixel based on radiation. In this TFT, it is desirable to implement a device configuration having high reliability with respect to radiation.

Accordingly, it is desirable to provide a radiation image pickup unit that makes it possible to implement a device configuration having high reliability, and a radiation image pickup display system including such a radiation image pickup unit.

A radiation linage pickup unit according to as embodiment of the disclosure includes: a plurality of pixels configured to generate signal charge based on radiation; and a field effect transistor for readout of the signal charge from the plurality of pixels, and the transistor includes a first silicon oxide film, a semiconductor layer including an active layer, and a second silicon oxide film stacked in order from substrate side, and a first gate electrode disposed to face the semiconductor layer with one of the first and the second silicon oxide films in between. The second silicon oxide film has a thickness equal to or larger than a thickness of the first silicon oxide film.

A radiation image pickup display system according to an embodiment of the disclosure includes the foregoing radiation image pickup unit of the disclosure and a display unit being configured to display an image based on an image pickup signal obtained by the radiation image pickup unit.

In the radiation image pickup unit and the radiation image pickup display system according to the respective embodiments of the disclosure, the transistor for readout of the signal charge from each of the pixels includes the first silicon oxide film, the semiconductor layer, and the second silicon oxide film that are stacked in order from the substrate side, and the first gate electrode that is disposed to face the semiconductor layer with one of the first and the second silicon oxide films in between. The thickness of the second silicon oxide film is equal to or larger than the thickness of the first silicon oxide film, which suppresses interface degradation on the second silicon oxide film side of the semiconductor layer in a manufacturing process and makes transistor characteristics favorable.

According to the radiation image pickup unit and the radiation image pickup display system of the respective embodiments of the disclosure, the transistor for readout of the signal charge based on the radiation from each of the pixels includes the first silicon oxide film, the semiconductor layer, and the second silicon oxide film that are stacked in order from the substrate side, and the first gage electrode that is disposed to face the semiconductor layer with one of the first and the second silicon oxide films in between. Since, here, the thickness of the second silicon oxide film is equal to or larger than the thickness of the first silicon oxide film, transistor characteristics are made favorable. This makes it possible to implement a device configuration having high reliability.

### BRIEF DESCRIPTION OF DRAWINGS

FIG. 1 is a block diagram illustrating an entire configuration of a radiation image pickup unit according to an embodiment of the disclosure.

FIG. 2A is a schematic view illustrating a schematic configuration of a pixel section in a case of an indirect conversion type.

FIG. 2B is a schematic view illustrating a schematic configuration of a pixel section in a case of a direct conversion type.

FIG. 3 is a circuit diagram illustrating a specific configuration example of a pixel and other components illustrated is FIG. 1.

FIG. 4 is a sectional view illustrating a configuration of a transistor illustrated in FIG. 2.

FIG. 5A is a TEM (Transmission Electron Microscope) photograph (corresponding to a configuration illustrated in FIG. 12) for describing film thicknesses of silicon oxide films.

FIG. 5B is a sectional view schematically illustrating a part of FIG. 5A.

FIG. 6 is a block diagram illustrating a specific configuration example of a column selection section illustrated in FIG. 1.

FIG. 7A is a characteristic diagram for describing an influence of X-rays on current-voltage characteristics of the transistor.

FIG. 7B is a sectional view for describing a manufacturing process including a process of forming a semiconductor layer.

FIG. 7C is a sectional view illustrating a process following FIG. 7B.

FIG. 7D is a sectional view illustrating a process following FIG. 7C.

FIG. 7E is a sectional view illustrating a process following FIG. 7D.

FIG. 7F is a characteristic diagram illustrating a relationship between the total of film thicknesses of silicon oxide films and a shift in threshold voltage.

FIG. 8 is a sectional view illustrating a configuration of a transistor according to Modification Example 1.

FIG. 9A is a diagram illustrating current-voltage characteristics before and after application of X-rays to a transistor according to Example 1.

FIG. 9B is a diagram illustrating current-voltage characteristics before and after application of X-rays to a transistor according to Example 2.

FIG. 10 is a characteristic diagram illustrating threshold voltage shift amounts in Examples 1 and 2.

FIG. 11 is a sectional view illustrating a configuration of a transistor according to Modification Example 2.

FIG. 12 is a sectional view illustrating a configuration of a transistor according to Modification Example 3-1.

FIG. 13 is a sectional view illustrating a configuration of a transistor according to Modification Example 3-2.

FIG. 14 is a circuit diagram illustrating a configuration of a pixel and other components according to Modification Example 4.

FIG. 15 is a circuit diagram illustrating a configuration of a pixel and other components according to Modification Example 5.

FIG. 16 is a circuit diagram illustrating a configuration of a pixel and other components according to Modification Example 6-1.

FIG. 17 is a circuit diagram illustrating a configuration of a pixel and other components according to Modification Example 6-2.

FIG. 18 is a schematic view illustrating a schematic configuration of an image pickup display system according to an application example.

### MODE FOR CARRYING OUT THE INVENTION

Some embodiments of the disclosure will be described in detail below with reference to the accompanying drawings. It is to be noted that description will be given in the following order.

1. Embodiment (An example of a radiation image pickup unit including a top-gate TFT in which a thickness of a silicon oxide film adjacent to top side of a semiconductor layer is larger than a thickness of a silicon oxide film adjacent to bottom side of the semiconductor layer)

2. Modification Example 1 (Another example of the top-gate transistor)

3. Modification Example 2 (An example of a bottom-gate transistor)

4. Modification Example 3-1 (An example of a dual-gate transistor)

5. Modification Example 3-2 (Another example of the dual-gate transistor)

6. Modification Example 4 (As example of another passive pixel circuit)

7. Modification Example 5 (An example of another passive pixel circuit)

8. Modification Examples 6-1 and 6-2 (An example of an active pixel circuit)

9. Application Example (An example of a radiation image pickup display system)

### EMBODIMENT

### [Configuration]

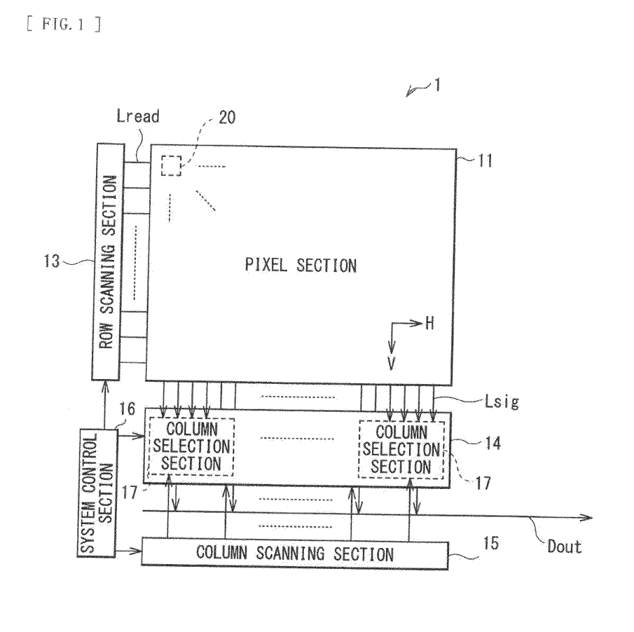

FIG. 1 illustrates a block configuration of an entire radiation image pickup unit (a radiation image pickup unit 1) according to an embodiment of the disclosure. The radiation image pickup unit 1 may, for example, read information of a subject (pick up an image of the subject) based on entering radiation Rrad (for example, α rays, β rays, γ rays, and X-rays). The radiation image pickup unit 1 includes a pixel section 11, and further includes, as drive circuits of the pixel section 11, a row scanning section 13, an A/D conversion section 14, a column scanning section 15, and a system control section 16.

(Pixel Section 11)

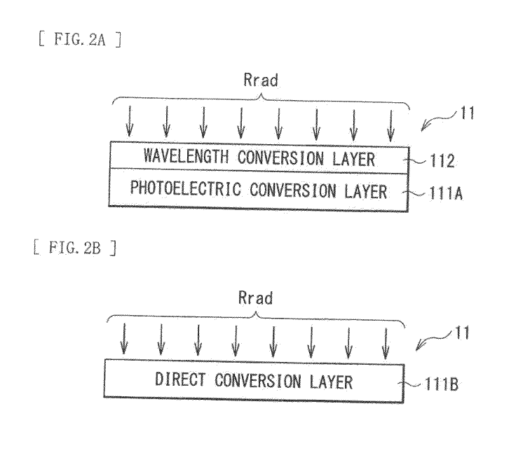

The pixel section 11 includes a plurality of pixels (image pickup pixels or unit pixels) 20 that, generate signal charge based on radiation. The pixels 20 are two-dimensionally arranged in an array (in a matrix). It is to be noted that, as illustrated in FIG. 1, in the following, a horizontal direction (a row direction) and a vertical direction (a column direction) in the pixel section 11 are respectively referred to as “H” direction and “V” direction. The radiation image pickup unit 1 may be either of a so-called indirect conversion type and a so-called direct conversion type, as long as the radiation image pickup unit 1 uses a transistor 22 to be described later as a switching device for readout of signal charge from the pixel section 11. FIG. 2A illustrates a configuration of the pixel section 11 in the indirect conversion type, and FIG. 2B illustrates a configuration of the pixel section 11, in the direct conversion type.

In the indirect conversion type (see FIG. 2A), the pixel section 11 includes a wavelength conversion layer 112 on a photoelectric conversion layer 111A (on light reception surface side). The wavelength, conversion layer 112 is configured to convert the radiation Rrad info radiation of a wavelength in a sensitivity region of the photoelectric conversion, layer 111 (for example, visible light). The wavelength conversion layer 112 may be configured of for example, a phosphor (for example, a scintillator such as CsI (Tl-added), Gd₂O₂S, BaFX (where X is Cl, Br, I, or any other element), NaI, and CaF₂) that converts, for example, X-rays into visible light. Such a wavelength conversion layer 112 may be formed on the photoelectric conversion layer 111A with a planarization film made of, for example, an organic material or a spin-on glass material in between. The photoelectric conversion layer 111A may include a photoelectric conversion device (a photoelectric conversion device 21 to be described later) such as a photodiode.

In the direct conversion type (see FIG. 2B), the pixel section 11 may include a conversion layer (a direct conversion layer 111B) that absorbs the entered radiation Rrad to generate electrical signals (holes and electrons). The direct conversion layer 111B may be made of for example, an amorphous selenium (a-Se) semiconductor or a cadmium tellurium (CdTe) semiconductor.

Although the radiation image pickup unit 1 may be either of the indirect conversion type and the direct conversion type, in the following embodiment and other following examples, mainly the indirect conversion type will be described as an example. In other words, as will be described in detail later, in the pixel section 11, the radiation Rrad is converted into visible light in the wavelength conversion layer 112, and thereafter, the visible light is converted into an electrical signal in the photoelectric conversion layer 111A (the photoelectric conversion device 21), and the electrical signal is read out as signal charge.

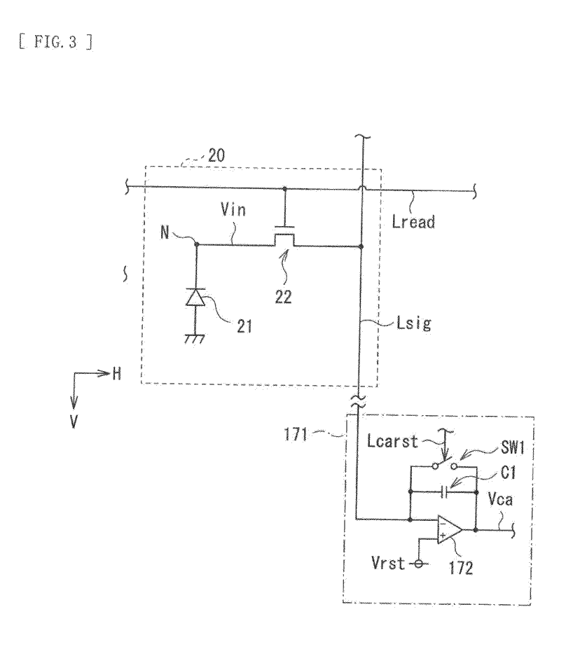

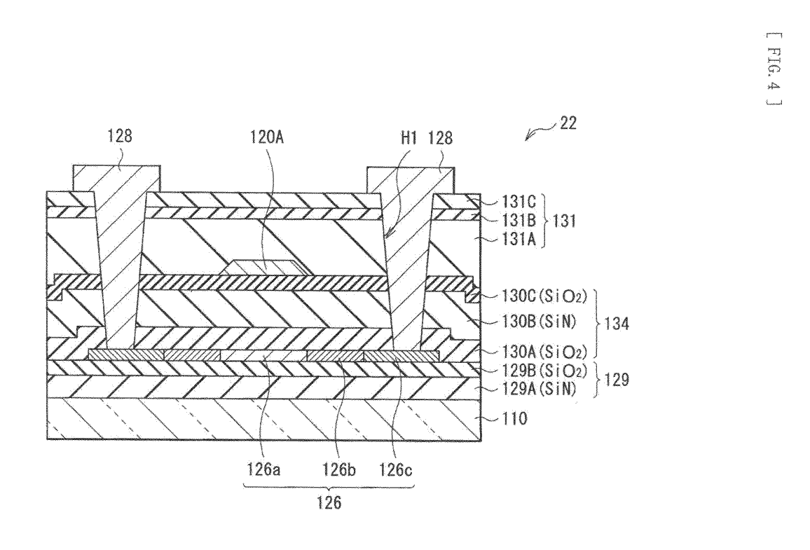

FIG. 3 illustrates an example of a circuit configuration (a so-called passive circuit configuration) of the pixel 20 together with a circuit configuration of a charge amplifier circuit 171 to be described later in the A/D conversion section 14. This passive pixel 20 includes one photoelectric conversion device 21 and one transistor 22. A readout control line Lread extending along the H direction and a signal line Lsig extending along the V direction are coupled to the pixel 20.

The photoelectric conversion device 21 may be configured of, for example, a PIN (Positive Intrinsic Negative) photodiode or a MIS (Metal-Insulator-Semiconductor) sensor, and generates signal charge of a charge amount corresponding to an entering light quantity, as described above. It is to be noted that, here, a cathode of the photoelectric con version device 21 is coupled to a storage node N.

The transistor 22 is a transistor (a readout transistor) that outputs the signal charge (an input voltage Vin) obtained by the photoelectric conversion device 21 to the signal line Lsig when turning to an ON state in response to a row scanning signal supplied through the readout control line Lread. Here, the transistor 22 is configured of an N-channel (N-type) field effect transistor (FET). Alternatively, the transistor 22 may be configured of a P-channel (P-type) FET or any other transistor.

FIG. 4 illustrates a sectional configuration of the transistor 22. In this embodiment, the transistor 22 has a device configuration of a so-called top-gate thin film transistor. The transistor 22 may include, for example, a first gate insulating film 129 (a first gate insulating film), a semiconductor layer 126, a second gate insulating film 130 (a second gate insulating film), and a first gate electrode 120A in this order on a substrate 110. An interlayer insulating film 131 is formed on the first gate electrode 120A, and a contact hole H1 that penetrates the interlayer insulating film 131 and the second gate insulating film 130 is formed. A source-drain electrode 128 is so provided on the interlayer insulating film 131 as to fill up the contact hole H1.

The semiconductor layer 126 may include, for example, a channel layer (active layer) 126a, an LDD (Lightly Doped Drain) layer 126b, and an N+ layer 126c, and may be made of, for example, a silicon-based semiconductor such as amorphous silicon, microcrystalline silicon, or polycrystalline silicon (polysilicon), and preferably low temperature poly-silicon (LTPS). Alternatively, the semiconductor layer 126 may be made of an oxide semiconductor such as indium gallium zinc oxide (InGaZnO) or zinc oxide (ZnO). The LDD layer 126b is formed between the channel layer 126a and the N+ layer 126c to reduce a leakage current.

The source-drain electrode 128 functions as a source or a drain, and may be a single-layer film made of, for example, one of elements including titanium (Ti), aluminum (Al), molybdenum (Mo), tungsten (W), and chromium (Cr), or a multilayer film including two or more of these elements.

The first gate electrode 120A may be, for example, a single-layer film made of one of elements including molybdenum, titanium, aluminum, tungsten, and chromium, or a multilayer film including two or more of these elements. The first gate electrode 120A is so disposed as to face the semiconductor layer 126 (more specifically, the channel layer 126a) with the second gate insulating film 130 in between (a region facing the first gate electrode 120A of the semiconductor layer 126 is the channel layer 126a).

(Configuration of Gate Insulating Film)

The first gate insulating film 129 and the second gate insulating film 130 may each include, for example, a silicon oxide film (an oxygen-containing silicon compound film) made of a material such as silicon oxide (SiOx) or silicon oxynitride (SiON). More specifically, the first gate insulating film 129 and the second gate insulating film 130 may each be a single-layer film made of a material such as silicon oxide or silicon oxyintride or a multilayer film including such a silicon oxide film and a silicon nitride film such as silicon nitride (SiNx) film. In both the first gate insulating film 129 and the second gate insulating film 130, the foregoing silicon oxide film is provided on the semiconductor layer 126 side (adjacent to the semiconductor layer 126). For example, in a case where the semiconductor layer 126 is made of low temperature poly-silicon, a silicon oxide film is formed adjacent to the semiconductor layer 126 for a manufacturing process reason.

The first gate insulating film 129 and the second gate insulating film 130 may each be preferably the foregoing multilayer film including the silicon oxide film and the silicon nitride film. Here, the first gate insulating film 129 and the second gate insulating film 130 are each a multilayer film. More specifically, the first gate insulating film 129 may include, for example, a silicon nitride film 129A and a silicon oxide film 129B stacked in order from the substrate 110 side. The second gate insulating film 130 may include, for example, a silicon oxide film 130A, a silicon nitride film 130B, and a silicon oxide film 130C stacked in order from the semiconductor layer 126 side. It is to be noted that, in this embodiment, the silicon oxide film 129B corresponds to a specific example of “first silicon oxide film” of the disclosure, and the silicon oxide film 130A corresponds to a specific example of “second silicon oxide film” of the disclosure.

In this embodiment, a thickness of the silicon oxide film 130A, which is adjacent to top side (a top surface) of the semiconductor layer 126, of the second gate insulating film 130 is equal to or larger than a thickness of the silicon oxide film 129B, which is adjacent to bottom side (a bottom surface) of the semiconductor layer 126, of the first gate insulating film 129. Moreover, the total of the thicknesses of the silicon oxide film 129B and the silicon oxide film 130A may be preferably, for example, 65 nm or less. This makes it possible to reduce a shift in a threshold voltage of the transistor 22 to negative side, thereby suppressing deterioration in characteristics.

As examples of the thicknesses of respective films in the first gate insulating film 129 and the second gate insulating film 130, for example, is the first gate insulating film 129, a thickness of the silicon nitride film 129A may be, for example, 30 nm to 120 nm both inclusive, and the thickness of the silicon oxide film 129B may be, for example, 5 nm to 60 nm both inclusive. In the second gate insulating film 130, the thickness of the silicon oxide film 130A may be, for example, 5 nm to 60 nm both inclusive, a thickness of the silicon nitride film 130B may be, for example, 10 nm to 120 nm both inclusive, and a thickness of the silicon oxide film 130C may be, for example, 5 nm to 60 nm both inclusive. In these film thickness ranges, each of the thicknesses of the silicon oxide films 129B and 130A is so set as to satisfy the foregoing magnitude relationship, and may be preferably so set that the total of the thicknesses is 65 nm or less.

Here, a capacitance (a gate capacitance) between the semiconductor layer 126 and the first gate electrode 120A is determined according to, for example but not limited to, dielectric constants and thicknesses of respective films forming the second gate insulating film 130. Since, as described above, the silicon oxide films 129B and 130A are adjacent to the semiconductor layer 126 for the manufacturing process reason, in terms of transistor characteristics (which will be described in detail later), the total of the thicknesses of the silicon oxide films 129B and 130A may be preferably relatively thin (for example, 65 nm or less). In the second gate insulating film 130, mainly the thickness of the silicon nitride film 130B is adjusted in the foregoing stacking configuration, which makes it possible to set the gate capacitance.

The thickness of the silicon nitride film 130B may be preferably larger than the thickness of the silicon oxide film 130A, and may be, for example, 10 nm or more. This makes it possible to easily form a desired gate capacitance while keeping the total of the thicknesses of the silicon oxide film 129A and the silicon oxide film 130B at, for example, 65 nm or less.

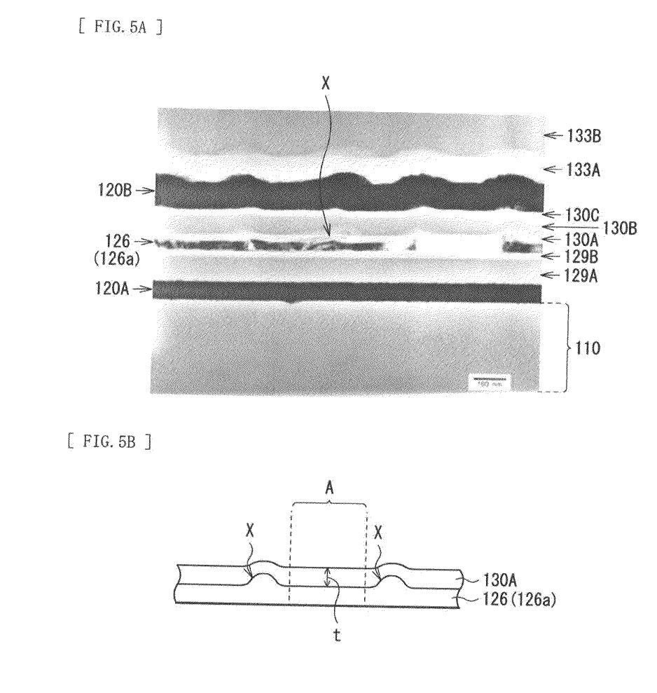

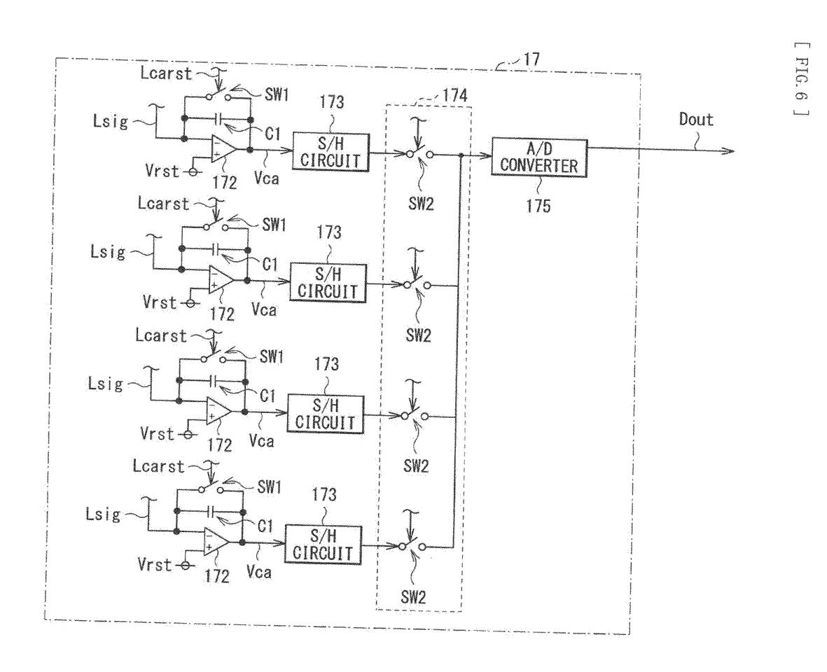

It is to be noted that the thickness of each of the films (specifically the silicon oxide film 130A) in the foregoing second gate insulating film 130 may be preferably measured, for example, at the following specific position. More specifically, as illustrated in FIG. 5A, in the stacking configuration of the transistor 22, an extremely small protrusion X is prone to be formed on a surface of the semiconductor layer 126 (the channel layer 126a) made of, for example, polycrystalline silicon. As a result, in respective films above the semiconductor layer 126, specifically the silicon oxide film 130A, it is difficult to obtain favorable coverage around the protrusion X (the respective films are prone to be thinned locally). Accordingly, as schematically illustrated in FIG. 5B, as the thickness of at least the silicon oxide film 130A of the second gate insulating film 130, a thickness (t) in a flat section A between the protrusions X may be preferably used.

The interlayer insulating film 131 may be a single-layer film made of, for example, one of materials including silicon oxide, silicon oxynitride, and the silicon nitride or a multilayer film including two or more of these materials. For example, the interlayer insulating film 131 may include, for example, a silicon oxide film 131A, a silicon nitride film 131B, and a silicon oxide bins 131C stacked in order from the first gate-electrode 120A side. It is to be noted that another interlayer insulating film may be further formed to cover the interlayer insulating film 131 and the scarce-drain electrode 128.

(Row Scanning Section 13)

The row scanning section 13 may include components such as a shift register circuit to be described later and a predetermined logical circuit, and is a pixel driving section (a row scanning circuit) that performs driving (line-sequential scanning), of the plurality of pixels 20 in the pixel section 11 row by row (by a horizontal line unit). More specifically, the row scanning section 13 may perform image pickup operation such as readout operation and reset operation of each of the pixels 20 by, for example, line-sequential scanning. It is to be noted that this line-sequential scanning is performed by supplying the foregoing row scanning signal to each of the pixels 20 through the readout control line Lread.

(A/D Conversion Section 14)

The A/D conversion section 14 includes a plurality of column selection sections 17 each provided for a plurality of (here, four) signal lines Lsig. The A/D conversion section 14 performs A/D conversion (analog-to-digital conversion), based on a signal voltage (a voltage corresponding to the signal charge) inputted through the signal line Lsig. As a result, output data Dout (an image pickup signal) that is a digital signal is generated and outputted to the outside.

For example, as illustrated in FIG. 6, each of the column selection sections 17 may include a charge amplifier 172, a capacitive device (such as a capacitor or a feedback capacitive device) C1, a switch SW1, a sample hold (S/H) circuit 173, a multiplexor circuit (a selection circuit) 174 including four switches SW2, and an A/D converter 175. Of these components, the charge amplifier 172, the capacitive device C1, the switch SW1, the S/H circuit 173, and the switch SW2 are provided for each of the signal lines Lsig. The multiplexor circuit 174 and the A/D converter 175 are provided for each of the column selection sections 17. It is to be noted that the charge amplifier 172, the capacitive device C1, and the switch SW1 form the charge amplifier circuit 171 illustrated in FIG. 3.

The charge amplifier 172 is an amplifier for conversion (Q-V conversion) from signal charge read out from the signal line Lsig to a voltage. In the charge amplifier 172, one end of the signal line Lsig is coupled to an input terminal on negative side (− side), and a predetermined reset voltage Vrst is inputted to an input terminal on positive side (+ side). Feedback connection is provided between an output terminal and the input terminal on negative side of the charge amplifier 172 through a parallel connection circuit including the capacitive device C1 and the switch SW1. In other words, one terminal and the other terminal of the capacitive device C1 are respectively coupled to the input terminal on negative side of the charge amplifier 172 and the output terminal of the charge amplifier 172. Similarly, one terminal and the other terminal of the switch SW1 are respectively coupled to the input terminal on negative side of the charge amplifier 172 and the output terminal of the charge amplifier 172. It is to be noted that an ON/OFF state of the switch SW1 is controlled by a control signal (an amplifier reset control signal) supplied from the system control section 16 through an amplifier reset control line Lcarst.

The S/H circuit 173 is provided between the charge amplifier 172 and the multiplexor circuit 174 (the switch SW2), and is a circuit configured to temporarily hold an output voltage Vca from the charge amplifier 172.

The multiplexor circuit 174 is a circuit that selectively makes or breaks connection between each of the S/H circuits 173 and the A/D converter 175 when one of the four switches SW2 is sequentially brought to the ON state according to scanning driving by the column scanning section 15.

The A/D converter 175 is a circuit that performs A/D conversion of an output voltage inputted from the S/H circuit 173 through the switch SW2, thereby generating and outputting the foregoing output data Dout.

(Column Scanning Section 15)

The column scanning section 15 may include, for example, an unillustrated shift register and an unillustrated address decoder, and is configured to sequentially drive each of the switches SW2 in the column selection section 17 while scanning each of the switches SW2. Such selection scanning by the column scanning section 15 allows the signal (the foregoing output data Dout) of each of the pixels 20 read out through each of the signal lines Lsig to be sequentially outputted to the outside.

(System Control Section 16)

The system control, section 16 is configured to control operation of each of the row scanning section 13, the A/D conversion section 14, and the column scanning section 15. More specifically, the system control section 16 includes a timing generator that generates the foregoing various timing signals (control signals), and performs driving control on the row scanning section 13, the A/D conversion section 14, and the column scanning section 15, based on these various timing signals generated by the timing generator. Based on such control of the system control section 16, each of the row scanning section 13, the A/D conversion section 14, and the column scanning section 15 performs image pickup driving (line-sequential image pickup driving) for the plurality of pixels 20 in the pixel section 11, thereby obtaining the output data Dout from the pixel section 11.

[Functions and Effects]

In the radiation image pickup unit 1 according to this embodiment, when, for example, the radiation Rrad such as X-rays enters foe pixel section 11, signal charge based on the entered light is generated in each of the pixels 20 (here, the photoelectric conversion devices 21). At this time, specifically, in the storage node N illustrated in FIG. 3, a voltage change according to a node capacitance is caused by accumulation of the thus-generated signal charge. Accordingly, an input voltage Vin (a voltage corresponding to the signal charge) is supplied to a drain of the transistor 22. Thereafter, when the transistor 22 is turned to the ON state in response to the row scanning signal supplied through the readout control line Lread, the foregoing signal charge is read out to the signal line Lsig.

The thus-read signal charge is inputted to the column selection section 17 in the A/D conversion section 14, for every plurality of (here, four) pixel columns, through the signal line Lsig. In the column selection section 17, first the Q-V conversion (conversion from the signal charge to the signal voltage) is performed for each signal charge inputted through each of the signal lines Lsig in the charge amplifier circuit including the charge amplifier 172 and the other components. Subsequently, the A/D conversion is performed on each signal voltage generated by the conversion (an output voltage Vca from the charge amplifier 172) in the A/D converter 175 through the S/H circuit 173 and the multiplexor circuit 174 to generate the output data Dout (the image pickup signal) that is a digital signal. Thus, the output data Dout is sequentially outputted from each of the column selection sections 17, and is transmitted to the outside (or is inputted to an unillustrated internal memory).

Some of the radiation Rrad having entered the radiation Image pickup unit 1 is not absorbed by the foregoing wavelength conversion layer 112 (or the direct conversion layer 111B) and is leaked to a layer therebelow, and when the transistor 22 is exposed to such radiation, the following defects may occur. The transistor 22 includes the silicon oxide films (the silicon oxide films 129B and 130A) in the first gate insulating film 129 and the second gale insulating film 130. When radiation enters these silicon oxide films, electrons in the films are excited by, for example but not limited to, a so-called photoelectric effect. Compton scattering, or electron-pair creation. As a result, holes are trapped and accumulated in the first gate insulating film 129 and the second gate insulating film 130, and holes are trapped and accumulated also at an interface with the channel layer 126a. This may cause, for example but not limited to, a shift in the threshold voltage Vth of the transistor 22 to negative side (minus side) or deterioration in an S (threshold) value, which may lead to an increase in off-current or a decrease in on-current.

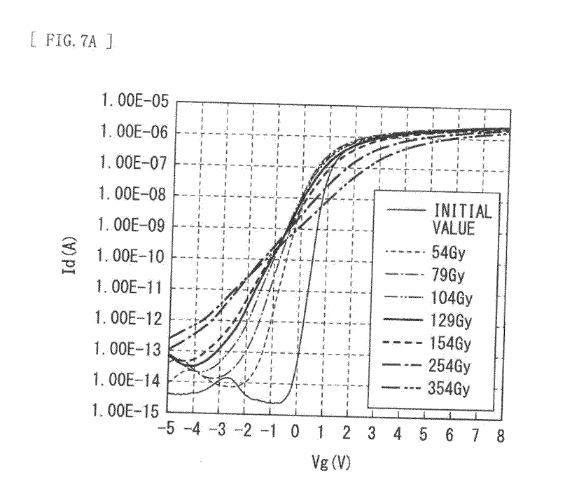

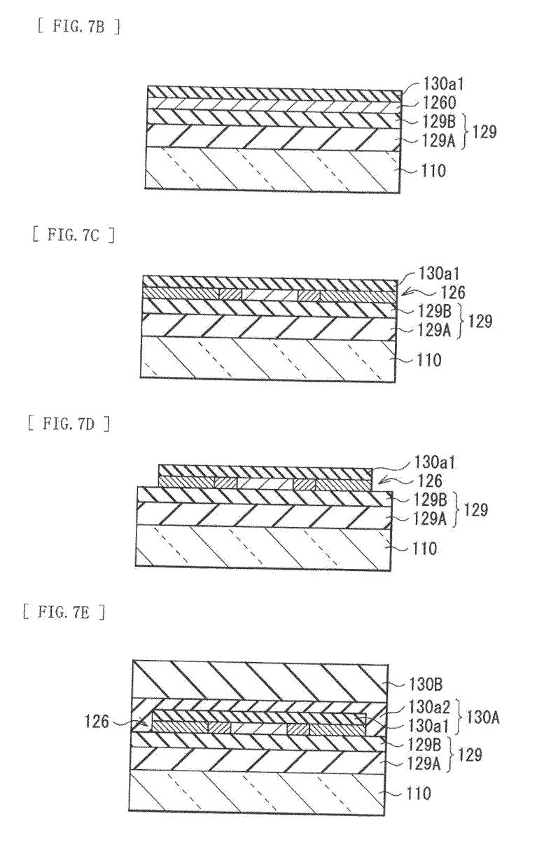

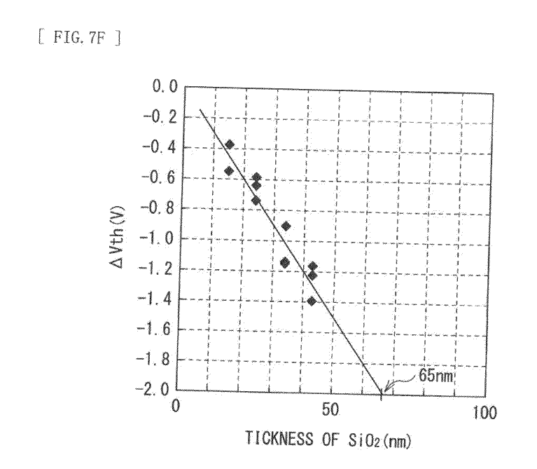

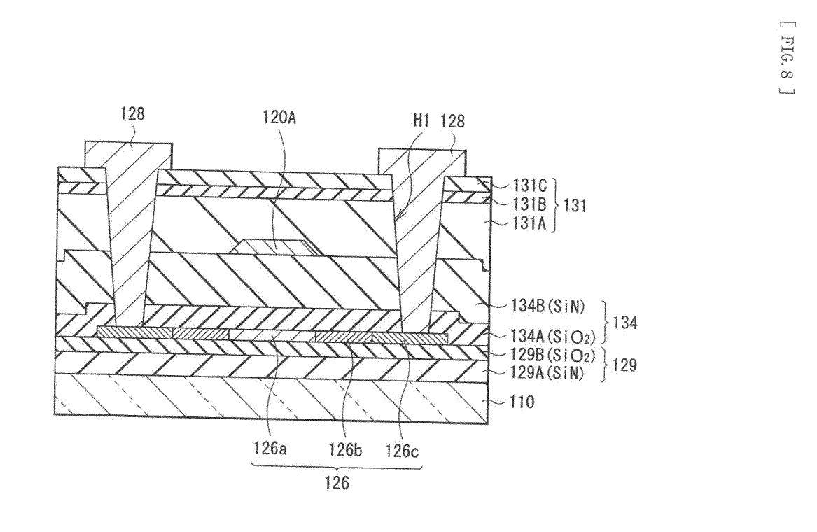

FIG. 7A illustrates, a relationship (current-voltage characteristics) of the drain current (a current between a source and a drain) Id with respect to a gate voltage Vg of the transistor 22 for each X-ray irradiation dose. Irradiation conditions include a tube voltage of 80 kV and a dose rate of 3.2 mGy/second, and the characteristics when an irradiation dose is 0 Gy (an initial value), 54 Gy, 79 Gy, 104 Gy, 129 Gy, 154 Gy, 254 Gy, and 354 Gy are illustrated. It is to be noted that the low temperature poly-silicon is used for the semiconductor layer 126, and a voltage Vds between the source and the drain is 0.1 V. It is found that, as the X-ray irradiation dose increases, the threshold voltage Vth (for example, the gate voltage Vg, where Id=1.0×10⁻¹³ A) shifts to negative side, and the S value deteriorates.

Here, in the transistor 22, as described above, a surface, of the semiconductor layer 126 is prone to be roughened (the protrusion X is prone to be formed), and the silicon oxide film 130A is prone to be thinned locally. When the thickness of the silicon oxide film 130A of the second gate insulating film 130 is equal to or larger than the thickness of the silicon oxide film 129B of the first, gate insulating film 129 as with this embodiment, for example, favorable coverage of the silicon oxide film 130A is obtained, which leads to favorable transistor characteristics (threshold voltage characteristics or S value). Moreover, this makes it possible to suppress, for example, the occurrence of variation in characteristics in each device.

Specifically, this is caused by the following reason. The reason is that when the semiconductor layer 126 is formed in a process of manufacturing the transistor 22, a stopper film (a stopper film 130a1) made of, for example, silicon oxide (SiO₂) is used. A case where the stopper film 130a1 is used will be described below as an example of a technique for obtaining the above-described favorable coverage; however, the stopper film 130a1 may not be necessarily formed.

Specifically, as illustrated in FIG. 7B, after a polysilicon layer 1260 is formed on the first gate insulating film 129 (after a crystallization process by ELA ), the stopper film 130a1 is formed on the polysilicon layer 1260. Subsequently, as illustrated in FIG. 7C, the polysilicon layer 1260 is doped with an impurity through the stopper film 130a1 to form the semiconductor layer 126. The stopper film 130a1 for formation of the semiconductor layer 126 is used in such a manner, which makes it possible to carry out the process without exposing (baring) the interface of the semiconductor layer 126 (specifically, the channel layer 126a). For this reason, interface degradation (such as contamination) in the semiconductor layer 126 is less prone to occur, and it is possible to suppress deterioration in characteristics. It is possible to carry out processes before the crystallization process, i.e., respective film formation processes up to the silicon nitride film 129A, the silicon oxide film 129B, and an amorphous silicon layer (corresponding to the semiconductor layer 126 before being crystallized) successively (without exposure to, for example but not limited to, air in a vacuum chamber). Accordingly, the interface on bottom side of the semiconductor layer 126 is resistant to degradation.

Thereafter, as illustrated in FIG. 7D, the semiconductor layer 126 and the stopper film 130a1 are patterned into a predetermined shape. An end surface (a side surface of an N⁺ layer 126c) is exposed by this patterning, and when, for example, the silicon nitride film 130B is formed in this state, the threshold voltage is easily shifted to negative side by an influence of an interface state. For this reason, as illustrated in FIG. 7E, a single-layer silicon oxide film 130a2 is further formed to cover the end surface of the semiconductor layer 126 and the stopper film 130a2. Thereafter, the silicon nitride film 130B may be preferably formed on the silicon oxide film 130a2. In other words, in the manufacturing process in order to maintain favorable transistor characteristics, the foregoing silicon oxide film 130A may preferably include the stepper film 130a1 and the silicon oxide film 130a2 (may be preferably formed by a multiple-stage film formation process).

For the foregoing reasons, the thickness of the silicon oxide film 130A above the semiconductor layer 126 is equal to or larger than the thickness of the silicon oxide film. 129B below the semiconductor layer 126, which makes it possible to suppress deterioration in transistor characteristics.

This makes the characteristics of the transistor 22 favorable. Moreover, as will be described later, it is specifically effective in a case where the total of the thicknesses of the silicon oxide films 129B and 130A adjacent to the semiconductor layer 126 is 65 nm or less (thin). This also makes it possible to suppress deterioration in characteristics caused by the foregoing hole trapping, thereby further enhancing reliability.

FIG. 7F illustrates a relationship between the total (total thickness) of the thicknesses of the silicon oxide (SiO₂) films and a shift amount (ΔVth) of the threshold voltage. It is to be noted that a symbol “− (minus)” on a vertical axis in the graph indicates that the threshold voltage shifts to negative side. The thicknesses of the silicon oxide films and the threshold voltage have such a relation therebetween, and the relation has linearity. For example, when the total of the thicknesses of the silicon oxide films 129B and 130A is 65 nm or less, this makes it possible to maintain the shift amount at 2 V or less and to secure a sufficient transistor lifetime.

As described above, in this embodiment, the transistor 22 for readout of signal charge based on the radiation. Rrad from each of the pixels 20 has a device configuration including the silicon oxide film 129B, the semiconductor layer 126, the silicon oxide film 130A, and the first gate electrode in order from the substrate 110 side. Since the thickness of the silicon oxide film 130A is equal to or larger than the thickness of the silicon, oxide film 129B, manufacturing yields of the transistor 22 are enhanced. This makes it possible to implement a device configuration having high reliability.

Next, modification examples of the foregoing embodiment will be described below. It is to be noted that like components are denoted by like numerals as of the foregoing embodiment, and the description thereof is appropriately omitted.

### MODIFICATION EXAMPLE 1

FIG. 8 illustrates a sectional configuration of a transistor according to Modification Example 1. In the foregoing embodiment (the example in FIG. 3), the second gate insulating film (the second gate insulating film 130) has a three-layer configuration including the silicon, oxide film 130A, the silicon nitride film 130B, and the silicon oxide film 130C stacked in order from the semiconductor layer 126 side; however, the multilayer configuration of the second gate insulating film is not limited thereto. For example, as with this modification example, a second gate insulating film (a second gate insulating film 134) may have a two-layer configuration including a silicon oxide film 134A and a silicon nitride film 134B stacked in order from the semiconductor layer 126 side.

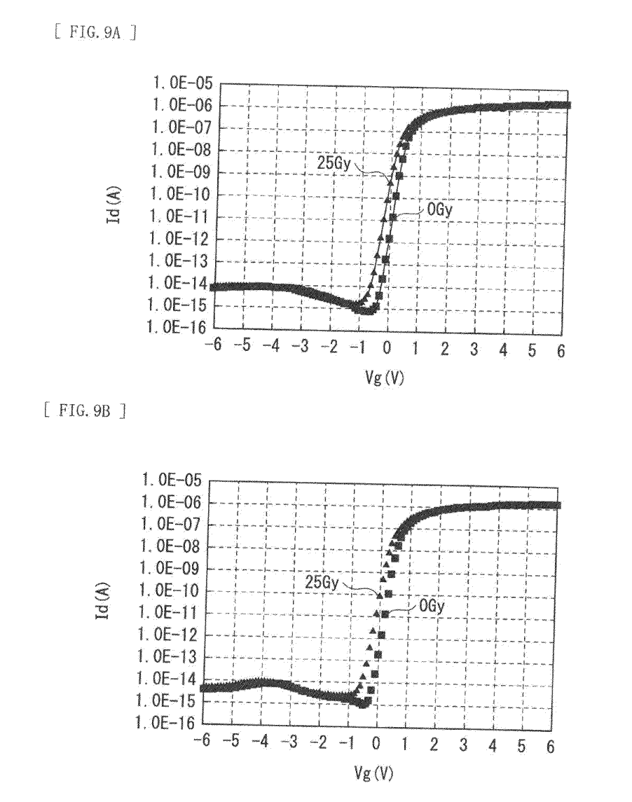

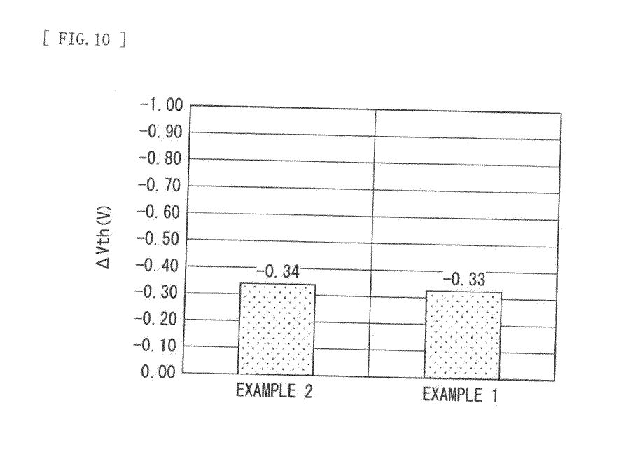

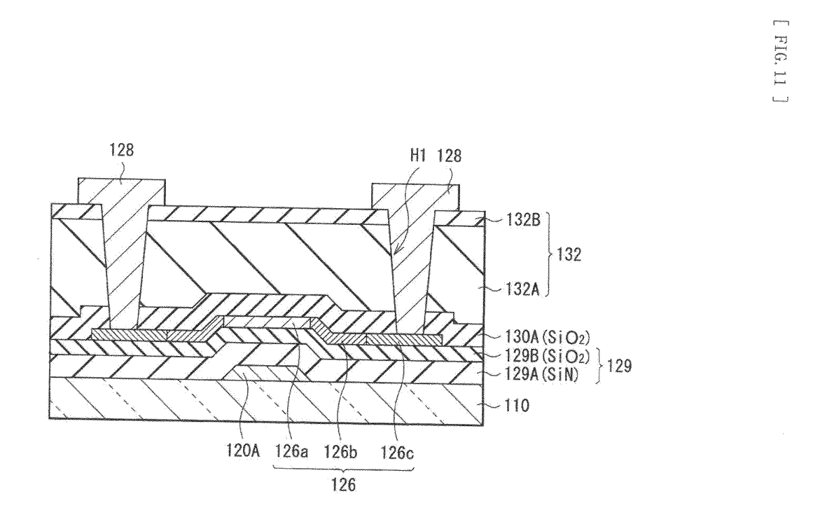

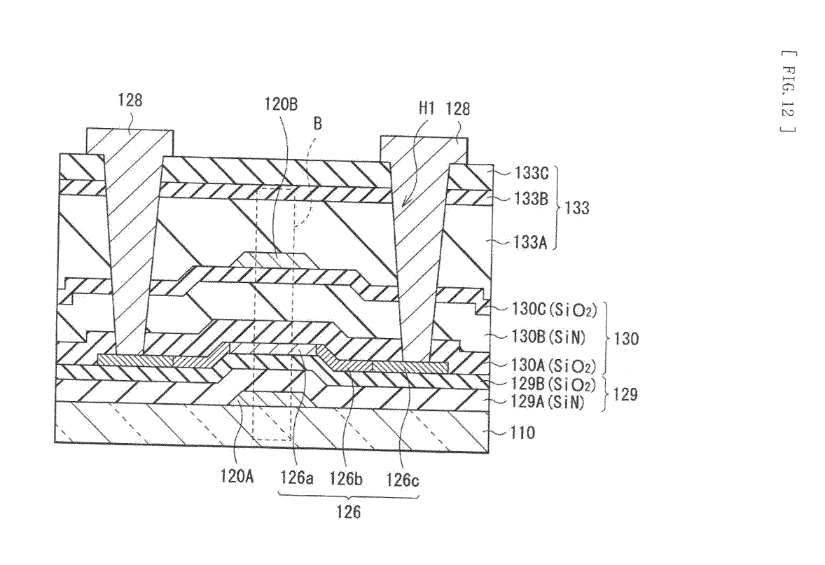

FIG. 9A illustrates current-voltage characteristics before and after application of X-rays to the transistor 22 in the foregoing embodiment (which is considered as Example 1), and FIG. 9B illustrates current-voltage characteristics before and after application of X-rays to the transistor in this modification example (which is considered as Example 2). X-ray irradiation conditions are similar to those in FIG. 7F, and cases where an X-ray irradiation dose was 0 Gy and 25 Gy are illustrated. Moreover, FIG. 10 illustrates threshold voltage shift amounts (ΔVth) after X-ray irradiation (25 Gy) in the current-voltage characteristics of Examples 1 and 2. As the threshold voltage Vth, a gate voltage in a case where tie current Id was 1.0×10⁻¹³ (A) was used. From these results, the current-voltage characteristics in the device configuration in this modification example were similar to those in the foregoing embodiment, and behavior by X-ray irradiation was also similar. Therefore, even in this modification example, it is possible to obtain similar effects to those in the foregoing embodiment. As long as the silicon oxide film 130A adjacent to the semiconductor layer 126 is formed with a thickness, equal to or larger than the thickness of the-silicon oxide film 129B, the second gate insulating film 130 may have a three-layer configuration or a two-layer configuration. Alternatively, although not illustrated, the second gate insulating film 130 may be configured of a single-layer film, for example, the silicon oxide film 130A.

### MODIFICATION EXAMPLE 2

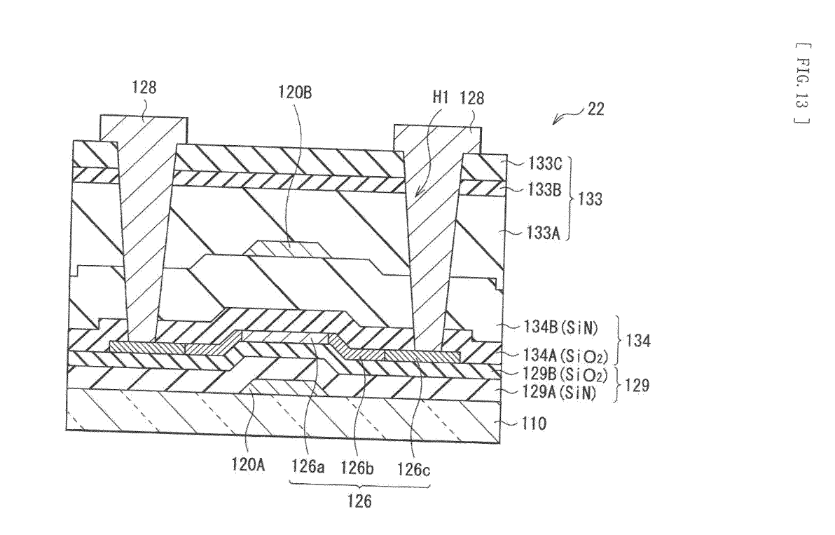

FIG. 11 illustrates a sectional configuration of a transistor according to Modification Example 2. in the foregoing embodiment, the top-gate device configuration is exemplified; however, the transistor of the disclosure may have a so-called bottom-gate device configuration as with this modification example. The device configuration of this modification example may include, for example, the first gate electrode 120A, the first gate insulating film 129, the semiconductor layer 126, and the silicon oxide film BOA in order from the substrate 110 side. Moreover, an interlayer insulating film 132 is formed on the silicon oxide film 130A, and the contact hole H1 that penetrates the interlayer insulating film 132 and the silicon oxide film 130A is formed. The source-drain electrode 128 is so provided on the interlayer insulating film 132 as to fill up the contact hole H1. The interlayer insulating film 132 may be, for example, a multilayer film including a silicon nitride film 132A and a silicon oxide film 132B in order from the silicon oxide film 130A side.

Even in this modification example, the thickness of the silicon oxide film 130A is equal to or larger than the thickness of the silicon oxide film 129B, which makes it possible to obtain similar effects to those in the foregoing embodiment. Moreover, a thickness of the silicon nitride film 132A of the Interlayer insulating film 132 may be preferably larger than the thickness of the silicon oxide film 130A (for example, 10 nm or more). Further, for a similar reason to that in the foregoing embodiment, the total of the thicknesses of the silicon oxide films 129B and 130a adjacent to the semiconductor layer 126 may be preferably 65 nm or less.

### MODIFICATION EXAMPLE 3-1

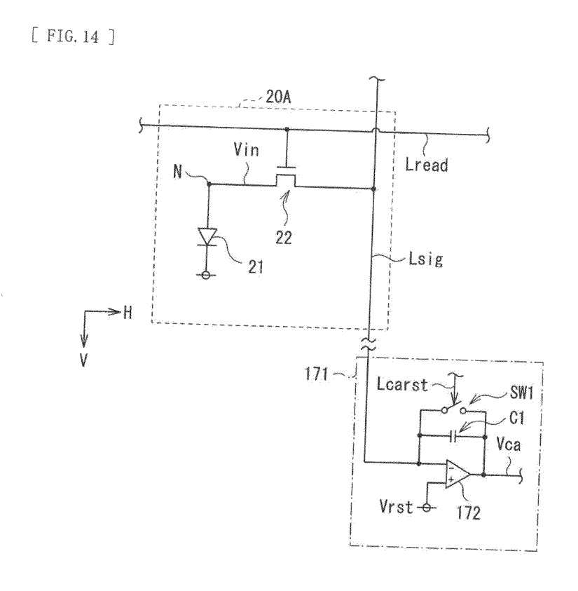

FIG. 12 illustrates a sectional configuration of a transistor according to Modification Example 3-1. In the foregoing embodiment, the top-gate device configuration is exemplified; however, the transistor of the disclosure may have a so-called dual-gate device configuration as with this modification example. The device configuration of this modification example may include, for example, the first gate electrode 120A, the first gate insulating film 129, the semiconductor layer 126, the second gate insulating film 130, and a second gate electrode 120B in order from the substrate 110 side. Moreover, an interlayer insulating film 133 is formed on the second gate insulating film 130 and the second gate electrode film 120B, and the contact hole H1 that penetrates the interlayer insulating film 133 and the second gate insulating film 130 is formed. The source-drain electrode 128 is so provided on the interlayer insulating film 133 as to fill up the contact hole H1. The interlayer insulating film 133 may be a multilayer film including a silicon oxide film 133A, a silicon nitride film 133B, and a silicon oxide film 133C in order from the silicon oxide film 130A side.

Even in this modification example, the thickness of the silicon oxide film 130A is equal to or larger than the silicon oxide film 129B, which makes it possible to obtain similar effects to those in the foregoing embodiment. Moreover, for a similar reason to that in the forgoing embodiment, the thickness of the silicon nitride film 132A of the interlayer insulating film 132 may be preferably larger than the thickness of the silicon oxide film 130A (for example, 10 nm or more). Further, for a similar reason to that in the foregoing embodiment, the total of the thicknesses of the silicon oxide films 129B and 130a adjacent to the semiconductor layer 126 may be preferably 65 nm or less.

### MODIFICATION EXAMPLE 3-2

FIG. 13 illustrates a sectional configuration, of a transistor according to Modification example 3-2, Even in the dual-gate device configuration in the foregoing Modification Example 3-1, the multilayer configuration of the second gate insulating film is not specifically limited, and the second gate insulating film 134 with a two-layer configuration described in the foregoing Modification Example 1 may be used.

### MODIFICATION EXAMPLE 4

FIG. 14 illustrates a circuit, configuration of a pixel, (a pixel 20A) according to Modification Example 4 together with a circuit configuration example of the charge amplifier circuit 171 described in the foregoing embodiment. The pixel 20A in this modification example has a so-called passive circuit configuration as with the pixel 20 in the embodiment, and includes one photoelectric conversion device 21 and one transistor 22. Moreover, the readout control line Lread extending along the H direction and the signal line Lsig extending along the V direction are coupled to the pixel 20.

However, in the pixel 20A in this modification example, unlike the pixel 20 in the foregoing embodiment, an anode of the photoelectric conversion device 21 is coupled to the storage node N, and a cathode is coupled to a ground. In the pixel 20A, the anode of the photoelectric conversion device 21 may be coupled to the storage node N in such a manner, and even such a configuration makes it possible to obtain similar effects to those of the radiation image pickup unit 1 according to the foregoing embodiment.

### MODIFICATION EXAMPLE 5

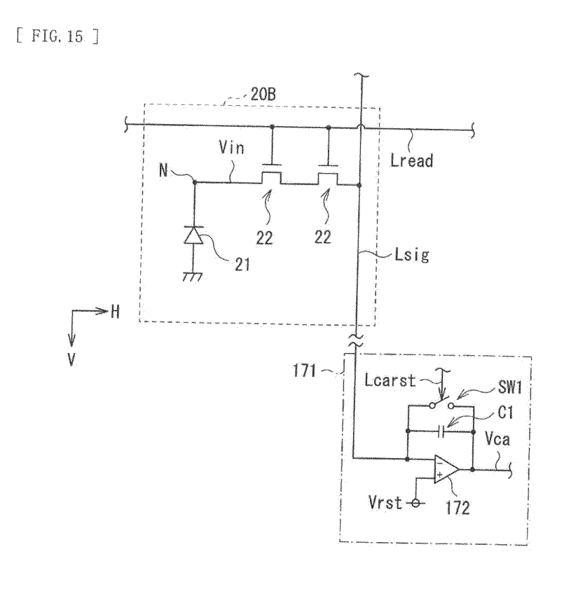

FIG. 15 illustrates a circuit configuration of a pixel (a pixel 20B) according to Modification Example 5 together with the circuit configuration example of the charge amplifier circuit 171 described in the foregoing embodiment. The pixel 20B in this modification example has a so-called passive circuit configuration as with the pixel 20 in the embodiment, and includes one photoelectric conversion device 21, and is coupled to the readout, control line Lread extending along the H direction and the signal line Lsig extending along the V direction.

However, in this modification example, the pixel 20B includes two transistors 22. The two transistors 22 are coupled in series to each other (a source or a drain of one of the transistors 22 is electrically coupled to a source or a drain of the other transistor 22). Two transistors 22 are provided in one pixel 20B in such a manner, which makes it possible to reduce off-leakage.

Two transistors 22 coupled in series to each other may be provided in the pixel 20B in such a manner, and even in this case, similar effects to those in the foregoing embodiment are obtainable. It is to be noted that three or more transistors may be coupled in series to one another.

### MODIFICATION EXAMPLES 6-1 and 6-2

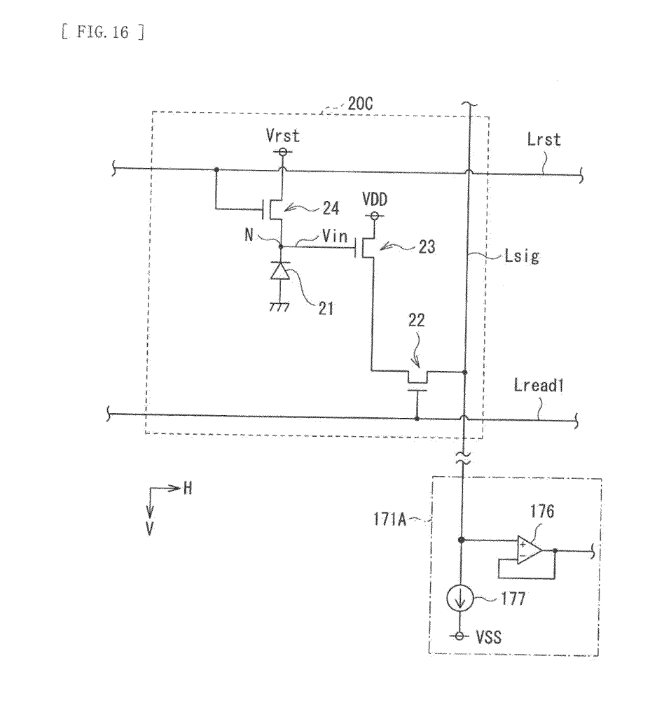

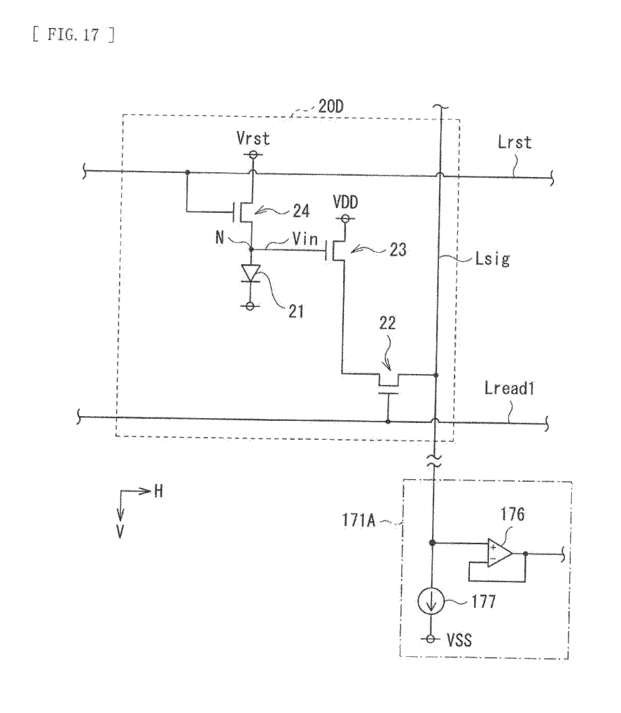

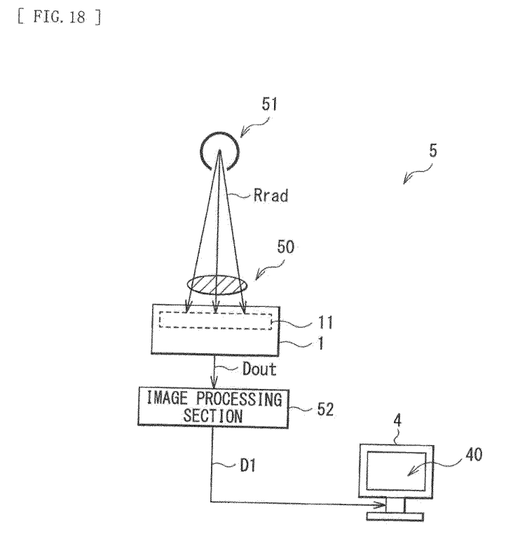

FIG. 16 illustrates a circuit configuration of a pixel (a pixel 20C) according to Modification Example 6-1 together with a circuit configuration example of a charge amplifier circuit 171A to be described later. Moreover, FIG. 17 illustrates a circuit configuration of a pixel (a pixel 20D) according to Modification Example 6-2 together with the circuit configuration example of the charge amplifier circuit 171A. The pixels 20C and 20D according to Modification Examples 6-1 and 6-2 are each different from the pixels 20, 20A, and 20B described above, and each have a so-called active pixel circuit.

The active pixels 20C and 20D each include one photoelectric conversion device 21 and three transistors 22, 23, and 24. The readout control line Lread and a reset control line Lrst extending along the H direction and the signal line. Lsig extending along the V direction are coupled to each of the pixels 20C and 20D.

In each of the pixels 20C and 20D, a gate, a source, and a drain of the transistor 22 are respectively coupled to the readout control line Lread, the signal line Lsig, and a drain of the transistor 23 forming a source follower circuit. A source of the transistor 23 is coupled to a power supply VDD, a gate thereof is coupled to the cathode (an example in FIG. 16) or the anode (an example in FIG. 17) of the photoelectric conversion device 21 and a drain of the transistor 24 functioning as a reset transistor through the storage node N. A gate of the transistor 24 is coupled to the reset control line Lrst, and a source thereof is supplied with a reset voltage Vrst. In Modification Example 6-1, the anode of the photoelectric conversion device 21 is coupled to the ground, and in Modification Example 6-2, the cathode of the photoelectric conversion device 21 is coupled to the ground.

Moreover, in these Modification Examples 6-1 and 6-2, the charge amplifier circuit 171A includes an amplifier 176 and a constant-current source 177 instead of the charge amplifier 172, the capacitive device C1, and the switch SW1 in the foregoing charge amplifier circuit 171. In the amplifier 176, an input terminal on positive side is coupled to the signal line Lsig, and an input terminal on negative side and an output terminal are coupled to each other, thereby forming a voltage follower circuit. It is to be noted that one terminal of the constant-current source 177 is coupled to one end of the signal line Lsig, and the other terminal of the constant-current source 177 is coupled to a power supply VSS.

The foregoing indirect conversion or direct conversion radiation image pickup unit is used as any of various radiation image pickup units that obtain an electrical signal based on the radiation Rrad. For example, the foregoing indirect conversion or direct conversion radiation image pickup unit may be applicable to medical X-ray image pickup units (such as digital radiography), X-ray radiographic units for inspection of carry-on items used at places such as airports, and industrial X-ray image pickup units (for example, a unit configured to inspect dangerous goods in a container)

### APPLICATION EXAMPLE

The radiation image pickup units according to the foregoing embodiment and the foregoing modification examples are applicable to a radiation image pickup display system to be described below.

FIG. 18 schematically illustrates a schematic configuration example of a radiation image pickup display system (a radiation image pickup display system 5) according to an application example. The radiation image pickup display system 5 includes the radiation image pickup unit 1 including the pixel section 11 and other

components according to one of the foregoing embodiment and the foregoing other examples, an image processing section 52, and a display unit 4, and is a radiation image pickup display system using radiation in this example.

The image processing section 52 performs predetermined image processing on the output data Dout (the image pickup signal) outputted from the radiation image pickup unit 1 to generate image data D1. The display unit 4 displays an image based on the image data D1 generated in the image processing section 52 on a predetermined monitor screen 40.

In the radiation, image pickup display system 5, the radiation image pickup unit 1 obtains the image data Dout of a subject 50 based on the radiation Rrad applied to the subject 50 from a radiation source 51 such as an X-ray source, and outputs the thus-obtained image data Dout to the image processing section 52. The image processing section 52 performs tire foregoing predetermined image processing on the inputted image data Dout, and outputs image data (display data) D1 generated by the image processing to the display unit 4. The display unit 4 displays image information (a picked-up image) on the monitor screen 40, based on the inputted image data D1.

In the radiation image pickup display system 5 of this application example, the radiation image pickup unit 1 is able to obtain the image of the subject 50 as an electrical signal in such a manner; therefore, transmission of the thus-obtained electrical, signal to the display unit 4 makes it possible to perform image display. In other words, this makes it possible to observe the image of the subject 50 without using a photographic film and to cope with moving image shooting and moving image display.

Although the embodiment, the modification examples, and the application example are described above, the contents of the disclosure are not limited thereto, and may be variously modified. For example, in the forgoing embodiment and the forgoing other examples, a film including one to three stacked insulating films is taken as an example of each of the first and second, gate insulating films; however, the first and the second gate insulating films may each be a film including four or more stacked insulating films. As long as the silicon oxide film of the second gate insulating film is provided on the semiconductor layer side, and is formed with a thickness equal to or larger than the silicon oxide film in the first gate insulating film, any multilayer configuration makes it possible to obtain effects of the disclosure.

Moreover, the circuit configuration of the pixel in the pixel section according to the foregoing embodiment and the foregoing other examples is not limited to those (the circuit configurations of the pixels 20, 20A to 20D) described in the foregoing embodiment and the foregoing other examples, and may be any other circuit configuration. Similarly, the circuit configurations of other components such as the row scanning section and the column selection section are not limited to those described in the foregoing embodiment and the foregoing other examples, and may be any other circuit configuration.

Further, the pixel section, the row scanning section, the A/D conversion section (the column selection section), the column scanning section, and other components that are described in the foregoing embodiment and the foregoing other examples may be formed, for example, on a same substrate. Specifically, for example, a polycrystalline semiconductor such as low temperature poly-silicon is used, which makes it possible to form the switch and other components in these circuit portions on the same substrate. This makes it possible to perform driving operation on the same substrate, based on, for example, a control signal from an external system control section, thereby achieving a slim bezel (a frame structure with three free sides) and an improvement in reliability in wiring connection.

It is to be noted that the disclosure may have the following configurations.

(1) A radiation image pickup unit including:

a plurality of pixels configured to generate signal charge based on radiation; and

a field effect transistor for readout of the signal charge from the plurality of pixels,

the transistor including

a first silicon oxide film, a semiconductor layer including an active layer, and a second silicon oxide film stacked m order from substrate side, and

a first gate electrode disposed to lace the semiconductor layer with one of the first and the second silicon oxide films in between, and

the second silicon oxide film having a thickness equal to or larger than a thickness of the first silicon oxide film.

(2) The radiation image pickup unit according to (1), in which the transistor includes the first silicon oxide film, the semiconductor layer, the second silicon oxide film, and the first gate electrode in order from the substrate side.

(3) The radiation image pickup unit according to (2), in which a silicon nitride film haying a larger thickness than the thickness of the second silicon oxide film is provided between the second silicon oxide film and the first gate electrode.

(4) The radiation image pickup unit according to (3), in which the thickness of the silicon nitride film is 10 am or more.

(5) The radiation image pickup unit according to any one of (1) to (4), in which the total of the thicknesses of the first and fee second silicon oxide films is 65 nm or less.

(6) The radiation image pickup unit according to (1), in which the transistor includes the first gale electrode, the first silicon oxide film, the semiconductor layer, and the second silicon oxide film in order from the substrate side.

(7) The radiation image pickup unit according to (6), in which a silicon nitride film having a larger thickness than the thickness of the second silicon oxide film is provided on the second silicon oxide film.

(8) The radiation image pickup unit according to (7), in which the thickness of the silicon nitride film is 10 nm or more.

(9) The radiation image pickup unit according to (1), in which

the transistor includes the first gate electrode, the first silicon oxide film, the semiconductor layer, and the second silicon oxide film in order from the substrate side, and

the transistor includes a second gate electrode on the second silicon oxide film to face the first gate electrode.

(10) The radiation image pickup unit according to 19), in which a silicon nitride film having a larger thickness than the thickness of the second silicon oxide film is provided between the second silicon oxide film and the first gate electrode.

(11) The radiation image pickup unit according to (10), in which the thickness of the silicon nitride film is 10 nm or more.

(12) The radiation image pickup unit according to any one of (1) to (11), in which the semiconductor layer includes one of polycrystalline silicon, microcrystalline silicon, amorphous silicon, and an oxide semiconductor.

(13) The radiation image pickup unit according to (12), in which the semiconductor layer includes low temperature poly-silicon.

(14) The radiation image pickup unit according to any one of (1) to (13), further including a wavelength conversion, layer on light entry side of the plurality of pixels,

in which each of the plurality of pixels includes a photoelectric conversion device, and

the wavelength conversion layer Is configured to convert the radiation into radiation of a wavelength in a sensitivity region of the photoelectric conversion device.

(15) The radiation image pickup unit according to (14), in which the photoelectric conversion device is configured of one of a PIN photodiode and a MIS sensor.

(16) The radiation image pickup unit according to any one of (1) to (13), in which each of the plurality of pixels includes a conversion layer that absorbs the radiation to generate the signal charge.

(17) The radiation image pickup unit according to any one of (1) to (16), in which the radiation includes X-rays.

(18) A radiation image pickup display system provided with a radiation image pickup unit and a display unit, the display unit being configured to display an image, based on an image pickup signal obtained by the radiation image pickup unit, the radiation image pickup unit including:

a plurality of pixels configured to generate signal charge based on radiation; and

a field effect transistor for readout of the signal charge horn the plurality of pixels,

the transistor including

a first silicon oxide film, a semiconductor layer including an active layer, and a second silicon oxide film stacked in order from substrate side, and

a first gate electrode disposed to face the semiconductor layer with one of the first and the second silicon oxide films in between, and

the second silicon oxide film having a thickness equal to or larger than a thickness of the first silicon oxide film,

This application claims the benefit of Japanese Priority Patent Application JP 2013-148271 filed on Jul. 17, 2013, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A radiation image pickup unit comprising:
a plurality of pixels configured to generate signal charge based on radiation; and
a field effect transistor for readout of the signal charge from the plurality of pixels,
the transistor including
a first silicon oxide film, a semiconductor layer including an active layer, and a second silicon oxide film stacked in order from substrate side, and
a first gate electrode disposed to face the semiconductor layer with one of the first and the second silicon oxide films in between, and
the second silicon oxide film having a thickness equal to or larger than a thickness of the first silicon oxide film.

2. The radiation image pickup unit according to claim 1, wherein the transistor includes the first silicon oxide film, the semiconductor layer, the second silicon oxide film, and the first gate electrode in order from the substrate side.

3. The radiation image pickup unit according to claim 2, wherein a silicon nitride film having a larger thickness than the thickness of the second silicon oxide film is provided between the second silicon oxide film and the first gate electrode.

4. The radiation image pickup unit according to claim 3, wherein the thickness of the silicon nitride film is 10 nm or more.

5. The radiation image pickup unit according to claim 1, wherein the total of the thicknesses of the first and the second silicon oxide films is 65 nm or less.

6. The radiation image pickup unit according to claim 1, wherein the transistor includes the first gate electrode, the first silicon oxide film, the semiconductor layer, and the second silicon oxide film in order from the substrate side.

7. The radiation image pickup unit according to claim 6, wherein a silicon nitride film having a larger thickness than the thickness of the second silicon oxide film is provided on the second silicon oxide film.

8. The radiation image pickup unit according to claim 7, wherein the thickness of the silicon nitride film is 10 nm or more.

9. The radiation image pickup unit according to claim 1, wherein
the transistor includes the first gate electrode, the first silicon oxide film, the semiconductor layer, and the second silicon oxide film in order from the substrate side, and
the transistor includes a second gate electrode on the second silicon oxide film to face the first gate electrode.

10. The radiation image pickup unit according to claim 9, wherein a silicon nitride film having a larger thickness than the thickness of the second silicon oxide film is provided between the second silicon oxide film and the first gate electrode.

11. The radiation image pickup unit according to claim 10, wherein the thickness of the silicon nitride film is 10 nm or more.

12. The radiation image pickup unit according to claim 1, wherein the semiconductor layer includes one of polycrystalline silicon, microcrystalline silicon, amorphous silicon, and an oxide semiconductor.

13. The radiation image pickup unit according to claim 12, wherein the semiconductor layer includes low temperature poly-silicon.

14. The radiation image pickup unit according to claim 1, further comprising a wavelength conversion, layer on light entry side of the plurality of pixels,
wherein each of the plurality of pixels includes a photoelectric conversion device, and
the wavelength conversion layer is configured to convert the radiation into radiation of a wavelength in a sensitivity region of the photoelectric conversion device.

15. The radiation image pickup unit according to claim 14, wherein the photoelectric conversion device is configured of one of a PIN photodiode and a MIS sensor.

16. The radiation image pickup unit according to claim 1, wherein each of the plurality of pixels includes a conversion layer that absorbs the radiation to generate the signal charge.

17. The radiation image pickup unit according to claim 1, wherein the radiation includes X-rays.

18. A radiation image pickup display system provided with a radiation image pickup unit and a display unit, the display unit being configured to display an image based on an image pickup signal obtained by the radiation, image pickup unit, the radiation image pickup unit comprising:
a plurality of pixels configured to generate signal charge based on radiation; and
a field effect transistor for readout of the signal charge from the plurality of pixels,
the transistor including
a first silicon oxide film, a semiconductor layer including an active layer, and a second silicon oxide film stacked in order from substrate side, and
a first gate electrode disposed to face the semiconductor layer with one of the first and the second silicon oxide films in between, and
the second silicon oxide film having a thickness equal to or larger than a thickness of the first silicon oxide film.
